(19) United States
(12) Patent Application Publication
(10) Pub. No.: US 2026/0122914 A1
(43) Pub. Date: Apr. 30, 2026

(54) SELECTOR AND MANUFACTURING METHOD THEREFOR

(71) Applicant: PEKING UNIVERSITY, Beijing (CN)

(72) Inventors: Zongwei WANG, Beijing (CN); Yimao CAI, Beijing (CN); Gaoqi YANG, Beijing (CN)

(73) Assignee: PEKING UNIVERSITY, Beijing (CN)

(21) Appl. No.: 19/371,670

(22) Filed: Oct. 28, 2025

(30) Foreign Application Priority Data
Oct. 29, 2024 (CN) 202411523701.3

(51) Int. Cl. H10B 63/00

(52) U.S. Cl. CPC H10B 63/20

(57) ABSTRACT

A selector and a manufacturing method therefor are provided. The selector includes a first electrode layer, a selection layer, a buffer layer, a barrier layer, and a second electrode layer. The selection layer, the buffer layer, and the barrier layer are stacked between the first electrode layer and the second electrode layer. An electron affinity of the barrier layer is less than an electron affinity of the selection layer, and an electron affinity of the buffer layer is between the electron affinity of the selection layer and the electron affinity of the barrier layer.

### CROSS-REFERENCE TO RELATED APPLICATIONS

The present disclosure claims priority to Chinese patent application No. 2024115237013, titled “SELECTOR AND MANUFACTURING METHOD THEREFOR”, filed on October 29, 2024, the entire content of which is incorporated herein by reference.

### TECHNICAL FIELD

The present disclosure relates to the field of integrated circuit technologies, and in particular, to a selector and a manufacturing method therefor.

### BACKGROUND

With the continuous development of fields such as artificial intelligence and autonomous driving, memories are being required to meet higher demands such as higher integration density and better reliability. A selector is a two-terminal nonlinear or threshold-switching device configured to select and control the on-off state of a memory cell. The selector can be combined with a memory to form a one-selector-one-resistor (1S1R) memory cell, such as Resistive Random-Access Memory (RRAM), Phase-Change Memory (PCRAM), Magnetoresistive Random-Access Memory (MRAM), or Ferroelectric Random-Access Memory (FeRAM). Incorporating the two-terminal selector into the memory cell can suppress a leakage current of a crossbar-structured memory array. In addition, compared to a three-terminal transistor (with a feature size of 6F²) configured for selection, the selector has a simpler structure (with a feature size of 4F²/N, where N is a quantity of stacking layers), thereby facilitates three-dimensional integration of memory cells.

However, a limited ability of selectors to suppress leakage current is still a challenging issue, hindering the practical application of 1S1R memory cells. Therefore, improving the leakage current suppression capability and reliability of selectors is crucial for improving the integration density of memory cells.

### SUMMARY

According to a first aspect, the present disclosure provides a selector. The selector includes a first electrode layer, a selection layer, a buffer layer, a barrier layer, and a second electrode layer. The selection layer, the buffer layer, and the barrier layer are stacked between the first electrode layer and the second electrode layer. An electron affinity of the barrier layer is less than an electron affinity of the selection layer, and an electron affinity of the buffer layer is between the electron affinity of the selection layer and the electron affinity of the barrier layer.

In some embodiments, a side surface of the selection layer is in contact with the first electrode layer, and a barrier is formed between the selection layer and the first electrode layer.

A barrier is formed between a side surface of the barrier layer away from the buffer layer and the second electrode layer.

In some embodiments, a difference between a work function of the first electrode layer and the electron affinity of the selection layer is greater than 2eV, and a difference between a work function of the second electrode layer and the electron affinity of the barrier layer is greater than 2eV.

In some embodiments, the electron affinity of the selection layer ranges from 2eV to 4.5eV, and the electron affinity of the barrier layer ranges from 1eV to 2eV.

In some embodiments, an oxygen content on a side of the buffer layer close to the barrier layer is greater than an oxygen content on a side of the buffer layer close to the selection layer.

In some embodiments, the oxygen content of the buffer layer gradually increases in a direction from the selection layer to the barrier layer.

In some embodiments, the selection layer includes multiple selection material layers, and an oxygen content of the selection material layer on a side away from the first electrode layer is greater than an oxygen content of the selection material layer on a side close to the first electrode layer.

In some embodiments, the oxygen contents of the multiple selection material layers gradually increase in a direction from the selection layer to the barrier layer.

In some embodiments, a material of the barrier layer comprises at least one of neodymium oxide, strontium oxide, germanium oxide, lanthanum oxide, hafnium oxide, gallium oxide, alumina, zirconium oxide, silicon oxide, ytterbium oxide, or magnesium oxide.

A material of the buffer layer comprises at least one of titanium oxide, nickel oxide, zinc oxide, chromium oxide, molybdenum oxide, tungsten oxide, bismuth oxide, antimony oxide, indium oxide, vanadium oxide, niobium oxide, manganese oxide, neodymium oxide, strontium oxide, germanium oxide, lanthanum oxide, hafnium oxide, gallium oxide, alumina, zirconium oxide, silicon oxide, yttrium oxide, or magnesium oxide.

A material of the selection layer includes at least one of niobium oxide, vanadium oxide, germanium telluride, germanium selenide, iron oxide, neodymium nickel oxide, samarium nickel oxide, lanthanum cobalt oxide, or gadolinium cobalt oxide.

According to a second aspect, the present disclosure provides a method for manufacturing a selector, including:

providing a substrate, and forming a first electrode layer on the substrate;

forming a selection layer on the first electrode layer;

forming a buffer layer on a side of the selection layer away from the first electrode layer;

forming a barrier layer on a side of the buffer layer away from the selection layer, wherein an electron affinity of the barrier layer is less than an electron affinity of the selection layer, and an electron affinity of the buffer layer is between the electron affinity of the selection layer and the electron affinity of the barrier layer; and

forming a second electrode layer on a side of the barrier layer away from the buffer layer.

In some embodiments, forming the buffer layer on the side of the selection layer away from the first electrode layer includes:

depositing a first conductive layer on the side of the selection layer away from the first electrode layer; and

after forming the barrier layer, annealing the selection layer, the first conductive layer, and the barrier layer, such that oxygen from the selection layer and the barrier layer oxidizes the first conductive layer to form the buffer layer.

In some embodiments, an oxygen content on a side of the buffer layer close to the barrier layer is greater than an oxygen content on a side of the buffer layer close to the selection layer.

In some embodiments, forming the selection layer on the first electrode layer includes:

sequentially depositing multiple selection material layers on the first electrode layer, an oxygen content of the selection material layer on a side away from the first electrode layer being greater than an oxygen content of the selection material layer on a side close to the first electrode layer.

### BRIEF DESCRIPTION OF THE DRAWINGS

In order to describe the technical solutions of the embodiments or the conventional technologies more clearly, the accompanying drawings required for describing the embodiments will be briefly introduced as follows. Apparently, the accompanying drawings in the following description illustrate merely some embodiments of the present disclosure, for a person of ordinary skill in the art, other drawings can also be obtained according to these accompanying drawings without making creative efforts.

FIG. 1 is a schematic structural diagram of a selector according to an embodiment.

FIG. 2 is a schematic structural diagram of a selector according to another embodiment.

FIG. 3 is a flowchart of a method for manufacturing a selector according to an embodiment.

### DETAILED DESCRIPTION OF THE EMBODIMENTS

For ease of understanding of the present disclosure, the following provides a more comprehensive description of the present disclosure with reference to related accompanying drawings. Preferred embodiments of the present disclosure are provided in the accompanying drawings. However, the present disclosure may be implemented in many different forms, and is not limited to the embodiments described herein. On the contrary, the purpose of providing these embodiments is to make the disclosure more thorough and comprehensive.

Unless otherwise defined, all technical and scientific terms used herein are of the same meaning as is commonly understood by those skilled in the art that fall within the scope of the present disclosure. The terms used in the specification of the present disclosure are merely intended to describe specific embodiments, and are not intended to limit the present disclosure.

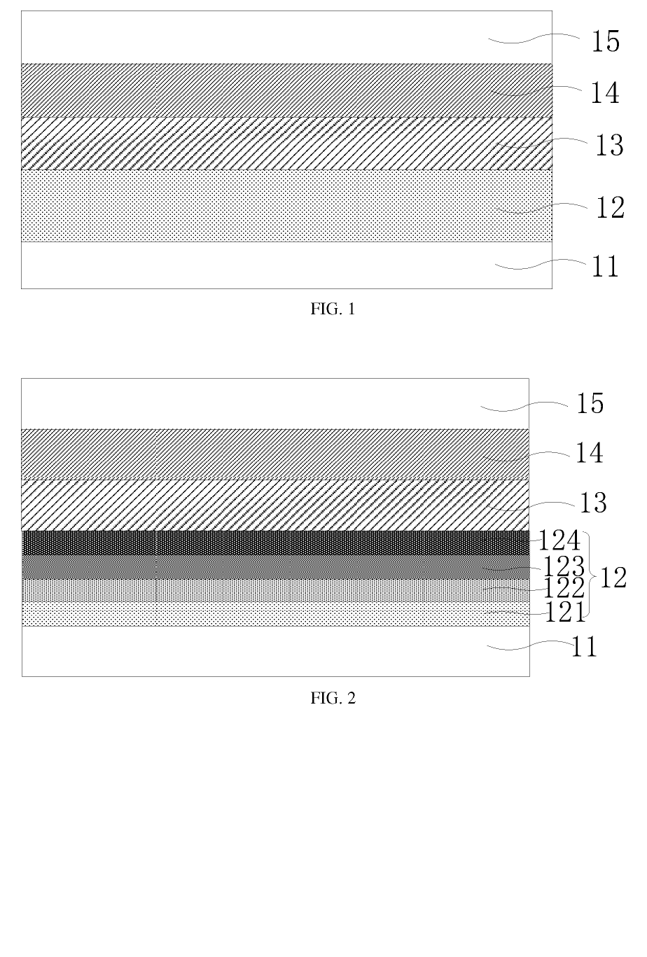

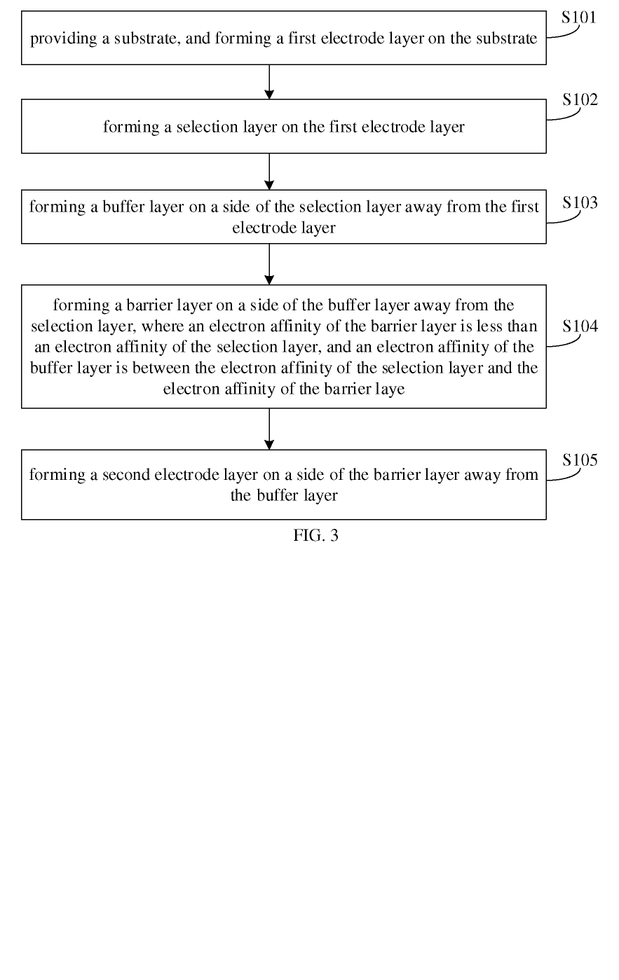

According to an exemplary embodiment, the present disclosure provides a selector. As shown in FIG. 1 or FIG. 2, the selector includes a first electrode layer 11, a selection layer 12, a buffer layer 13, a barrier layer 14, and a second electrode layer 15. The selection layer 12, the buffer layer 13, and the barrier layer 14 are stacked between the first electrode layer 11 and the second electrode layer 15. An electron affinity of the barrier layer 14 is less than an electron affinity of the selection layer 12, and an electron affinity of the buffer layer 13 is between the electron affinity of the selection layer 12 and the electron affinity of the barrier layer 14.

The buffer layer 13 and the barrier layer 14 that are sequentially stacked are disposed between the selection layer 12 and the first electrode layer 11, and/or between the selection layer 12 and the second electrode layer 15. In an example, a buffer layer 13 and a barrier layer 14 that are sequentially stacked are disposed between the selection layer 12 and the first electrode layer 11. In another example, a buffer layer 13 and a barrier layer 14 that are sequentially stacked are disposed between the selection layer 12 and the second electrode layer 15. In still another example, a buffer layer 13 and a barrier layer 14 that are sequentially stacked are disposed between the selection layer 12 and the first electrode layer 11, and a buffer layer 13 and a barrier layer 14 that are sequentially stacked are also disposed between the selection layer 12 and the second electrode layer 15.

The electron affinity of the barrier layer 14 is less than the electron affinity of the selection layer 12, the barrier layer 14 is disposed between the selection layer 12 and the first electrode layer 11 or between the selection layer 12 and the second electrode layer 15, and the barrier layer 14 is configured to confine electrons, so as to avoid leakage of electrons, thereby reducing a leakage current of the selector.

A buffer layer 13 is disposed between the selection layer 12 and the barrier layer 14, and the electron affinity of the buffer layer 13 is between the electron affinity of the selection layer 12 and the electron affinity of the barrier layer 14, so as to smooth the electron affinity transition between the selection layer 12 and the barrier layer 14, thereby avoiding performance fluctuation in the selector caused by a large electron affinity difference between the selection layer 12 and the barrier layer 14, improving the performance stability of the selector. In addition, when the selector is turned on, the selection layer 12 switches from a high-resistance state to a low-resistance state, and a partial voltage of the barrier layer 14 increases. In the present disclosure, the buffer layer 13 is disposed between the selection layer 12 and the barrier layer 14, so that the buffer layer 13 can reduce the partial voltage of the barrier layer 14, preventing the barrier layer 14 from being breakdown by high partial voltage, thereby further reducing a risk of leakage of the selector, improving the performance stability and reliability of the selector, and optimizing performance and prolonging a service life of the device.

In some embodiments, referring to FIG. 1 or FIG. 2, a breakdown voltage of the buffer layer 13 is greater than a breakdown voltage of the barrier layer 14. In this way, the barrier layer 14 can be further prevented from being breakdown by a high partial voltage when the selector is turned on, thereby further reducing a risk of leakage of the selector, improving performance stability and reliability of the selector, and optimizing performance of a device and prolonging a service life of the device.

In some embodiments, referring to FIG. 1 or FIG. 2, the buffer layer 13 has improved lattice matching with the selection layer 12, which prevents an adverse effect caused by interface mismatch between the selection layer 12 and the barrier layer 14. In addition, the buffer layer 13 exhibits a stronger adhesion to the selection layer 12, thereby avoiding issues such as delamination or peeling between the layers of the selector, improving structural stability of the selector.

In some embodiments, referring to FIG. 1 or FIG. 2, a side surface of the selection layer 12 is in contact with the first electrode layer 11, and a barrier is formed between the selection layer 12 and the first electrode layer 11. A barrier is formed between a side surface of the barrier layer 14 away from the buffer layer 13 and the second electrode layer 15.

In the embodiment, the buffer layer 13 and the barrier layer 14 that are sequentially stacked are disposed between the selection layer 12 and the second electrode layer 15, such that electrons can be confined at the barrier between the selection layer 12 and the first electrode layer 11, as well as at the barrier between the barrier layer 14 and the second electrode layer 15, so as to avoid electron leakage, thereby reducing a leakage current of the selector.

In some embodiments, a difference between a work function of the first electrode layer 11 and the electron affinity of the selection layer 12 is greater than 2eV. A difference between a work function of the second electrode layer 15 and the electron affinity of the barrier layer 14 is greater than 2eV.

In some embodiments, the electron affinity of the selection layer 12 ranges from 2eV to 4.5eV. The electron affinity of the barrier layer 14 ranges from 1eV to 2eV. The electron affinity of the buffer layer 13 ranges from 1eV to 4.5eV.

In some embodiments, referring to FIG. 1 or FIG. 2, an oxygen content on the side of the buffer layer 13 close to the barrier layer 14 is greater than an oxygen content on the side of the buffer layer 13 close to the selection layer 12. In the embodiments, by regulating oxygen contents in different sides of the buffer layer 13, the electron affinity of the buffer layer 13 near the barrier layer 14 is adjusted to close to the electron affinity of the barrier layer 14, and the electron affinity of the buffer layer 13 near the selection layer 12 is close to the electron affinity of the selection layer 12, thereby further avoiding performance fluctuation of the selector caused by the large electron affinity difference between the selection layer 12 and the barrier layer 14, further improving the performance stability of the selector.

In some embodiments, referring to FIG. 1 or FIG. 2, in the direction from the selection layer 12 to the barrier layer 14, the oxygen content in the buffer layer 13 gradually increases. In the embodiments, in the direction from the selection layer 12 to the barrier layer 14, the electron affinity of the buffer layer 13 gradually changes, such that a smooth transition of the electron affinity across the selection layer 12, the buffer layer 13, and the barrier layer 14 is achieved, thereby avoiding performance fluctuation of the selector caused by the large electron affinity difference between the selection layer 12 and the barrier layer 14, and improving the stability and performance of the selector.

In some embodiments, referring to FIG. 1 or FIG. 2, the selection layer 12 includes multiple selection material layers, and an oxygen content of the selection material layer on the side away from the first electrode layer 11 is greater than an oxygen content of the selection material layer on the side close to the first electrode layer 11. In this way, the electron affinity of the contact interface between the selection layer 12 and the buffer layer 13 changes more smoothly, thereby further improving the stability and performance of the selector.

In an example, referring to FIG. 2, the selection layer 12 includes a first selection material layer 121, a second selection material layer 122, a third selection material layer 123, and a fourth selection material layer 124 that are sequentially stacked. A material of the first selection material layer 121 includes niobium monoxide (NbO), a material of the second selection material layer 122 includes niobium dioxide (NbO₂), a material of the third selection material layer 123 includes niobium trioxide (Nb₂O₃), and a material of the fourth selection material layer 124 includes oxygen-deficient niobium pentoxide (Nb₂O_{5-y}).

In some embodiments, referring to FIG. 1 or FIG. 2, the oxygen contents of the multiple selection material layers gradually increase in the direction from the selection layer 12 to the barrier layer 14. In this way, in the direction from the selection layer 12 to the barrier layer 14, the electron affinity of the selection layer 12 changes smoothly, thereby further weakening the difference between the electron affinity of the selection layer 12 and the electron affinity of the barrier layer 14, improving the stability and performance of the selector.

In some embodiments, referring to FIG. 1 or FIG. 2, the barrier layer 14 includes multiple barrier material layers, and an oxygen content of the barrier material layer on the side away from the buffer layer 13 is greater than an oxygen content of the barrier material layer on the side close to the buffer layer 13. The difference between the electron affinity of the selection layer 12 and the electron affinity of the barrier layer 14 is further weakened.

In the direction from the selector layer 12 to the barrier layer 14, the oxygen content of the multiple barrier material layers gradually increases, further weakening the difference between the electron affinity of the selection layer 12 and the electron affinity of the barrier layer 14.

In some embodiments, the material of the selection layer 12 includes metal oxide. An oxygen affinity of the buffer layer 13 is less than an oxygen affinity of the barrier layer 14. In this way, by arranging the buffer layer 13 between the selection layer 12 and the barrier layer 14, oxygen loss of the selector can be reduced, thereby enhancing the stability of operational performance of the selector and prolonging the service life of the selector.

In some embodiments, the material of the barrier layer 14 includes at least one of neodymium oxide (NdOₓ), strontium oxide (SrOₓ), germanium oxide (GeOₓ), lanthanum oxide (LaOₓ), hafnium oxide (HfOₓ), gallium oxide (GaOₓ), alumina (AlOₓ), zirconium oxide (ZrOₓ), silicon oxide (SiOₓ), ytterbium oxide (YbOₓ), or magnesium oxide (MgOₓ).

The material of the buffer layer 13 includes at least one of titanium oxide (TiOₓ), nickel oxide (NiOₓ), zinc oxide (ZnOₓ), chromium oxide (CrOₓ), molybdenum oxide (MoOₓ), tungsten oxide (WOₓ), bismuth oxide (BiOₓ), antimony oxide (SbOₓ), indium oxide (InOₓ), vanadium oxide (VOₓ), niobium oxide (NbOₓ), manganese oxide (MnOₓ), neodymium oxide (NdOₓ), strontium oxide (SrOₓ), germanium oxide (GeOₓ), lanthanum oxide (LaOₓ), hafnium oxide (HfOₓ), gallium oxide (GaOₓ), alumina (AlOₓ), zirconium oxide (ZrOₓ), silicon oxide (SiOₓ), Ytterbium Oxide (YbOₓ) or magnesium oxide (MgOₓ).

The material of the selection layer 12 includes at least one of niobium oxide (NbOₓ), vanadium oxide (VOₓ), germanium telluride (GeTeₓ), germanium selenide (GeSeₓ), iron oxide (FeOₓ), neodymium oxide nickel (NdNiOₓ), samarium nickel oxide (SmNiOₓ), lanthanum cobalt oxide (LaCoOₓ), and gadolinium cobalt oxide (GdCoOₓ).

In some embodiments, referring to FIG. 1 or FIG. 2, the material of the selection layer 12 includes metal oxide. The material of the buffer layer 13 includes metal oxide or non-metal oxide. The material of the barrier layer 14 includes metal oxide or non-metal oxide. The buffer layer 13 is in contact with the selection layer 12. During the operation of the selector, oxygen in the selection layer 12 may be captured by the first electrode layer 11. The buffer layer 13 can supply oxygen to the selection layer 12, so as to maintain a balance of oxygen content in the selection layer 12, thereby improving performance stability of the selector.

In an example, the selector includes a first electrode layer 11, a selection layer 12, a buffer layer 13, a barrier layer 14, and a second electrode layer 15 that are sequentially stacked, a material of the selection layer 12 includes niobium oxide, a material of the buffer layer 13 includes titanium nitride, and a material of the barrier layer 14 includes alumina.

According to an exemplary embodiment, as shown in FIG. 3 and with reference to FIG. 1 and FIG. 2, the present disclosure provides a method for manufacturing a selector, including the following steps S101 to S105.

In step S101, a substrate is provided, and a first electrode layer 11 is formed on the substrate.

In step S102, a selection layer 12 is formed on the first electrode layer 11.

In step S103, a buffer layer 13 is formed on a side of the selection layer 12 away from the first electrode layer 11.

In step S104, a barrier layer 14 is formed on a side of the buffer layer 13 away from the selection layer 12, where an electron affinity of the barrier layer 14 is less than an electron affinity of the selection layer 12, and an electron affinity of the buffer layer 13 is between the electron affinity of the selection layer 12 and the electron affinity of the barrier layer 14.

In step S105, a second electrode layer 15 is formed on a side of the barrier layer 14 away from the buffer layer 13.

According to the method for manufacturing the selector in the embodiment, the buffer layer 13 and the barrier layer 14 are sequentially formed between the selection layer 12 and the second electrode layer 15. The barrier layer 14 is configured to confine electrons, thus preventing electron leakage, and reducing a leakage current of the selector. The buffer layer 13 is configured to smooth the electron affinity transition between the selection layer 12 and the barrier layer 14, thereby avoiding performance fluctuation in the selector caused by a large electron affinity difference between the selection layer 12 and the barrier layer 14, improving the performance stability of the selector. In addition, when the selector is turned on, the selection layer 12 switches from a high-resistance state to a low-resistance state, and a partial voltage of the barrier layer 14 increases. The buffer layer 13 can reduce the partial voltage of the barrier layer 14, preventing the barrier layer 14 from being breakdown by high voltage, thereby further reducing a risk of leakage of the selector, improving the performance stability and reliability of the selector, and help to optimize performance and prolong a service life of the selector.

In step S101, the substrate (not shown in the figure) may be a semiconductor substrate. A material of the semiconductor substrate may include, for example, silicon (Si), germanium (Ge), germanium silicon (SiGe), silicon carbide (SiC), gallium arsenide (GaAs), gallium nitride (GaN), or the like. Alternatively, in some cases, the substrate may be a silicon-on-insulator (SOI) substrate, such as silicon on glass (SOG) or silicon on sapphire (SOP).

The first electrode layer 11 may be deposited and formed on the substrate by using Physical Vapor Deposition (PVD), Chemical Vapor Deposition (CVD), Plasma Enhanced Chemical Vapor Deposition (PECVD), or Atomic Layer Deposition (ALD).

Referring to FIG. 1 and FIG. 2, a material of the first electrode layer 11 may include one or more of vanadium, niobium, ruthenium, tungsten, tantalum nitride, titanium, titanium nitride, titanium tungsten, aluminum, titanium aluminum tungsten, aluminum nitride, aluminum titanium nitride, hafnium, iridium, manganese, zinc, platinum, palladium, copper, or an alloy of the foregoing material. The first electrode layer 11 may be a single-layer structure or a multi-layer structure.

For example, a thickness of the first electrode layer 11 may be 10nm-2500nm.

In step S102, referring to FIG. 1 and FIG. 2, the selection layer 12 may be formed on the first electrode layer 11 by using PVD, PECVD, ALD, an ion beam sputtering process, an electron beam evaporation process, or a thermal evaporation process.

For example, a material of the selection layer 12 includes at least one of niobium oxide, vanadium oxide, germanium telluride, germanium selenium, iron oxide, neodymium nickel oxide, samarium nickel oxide, lanthanum cobalt oxide, or gadolinium cobalt oxide.

For example, the selection layer 12 may include a single selection material layer or multiple selection material layers that are sequentially stacked.

In some embodiments, in a process of depositing the selection layer 12, a conductive material is doped into the selection layer 12, so as to improve conductivity of the selection layer 12.

For example, ion implantation (IMP) and/or co-sputtering (Co-Sputter) can be employed to dope the conductive material into the selection layer 12.

For example, the conductive material doped to the selection layer 12 may include one or more of Al, Cu, Au, Ti, or the like.

In step S103, referring to FIG. 1 and FIG. 2, the buffer layer 13 may be formed by using PVD, CVD, or ALD. The electron affinity of the buffer layer 13 is less than the electron affinity of the selection layer 12.

For example, a material of the buffer layer 13 may include at least one of titanium oxide, nickel oxide, zinc oxide, chromium oxide, molybdenum oxide, tungsten oxide, bismuth oxide, antimony oxide, indium oxide, vanadium oxide, niobium oxide, manganese oxide, neodymium oxide, strontium oxide, germanium oxide, lanthanum oxide, hafnium oxide, gallium oxide, alumina, zirconium oxide, silicon oxide, ytterbium oxide, or magnesium oxide.

For example, the buffer layer 13 may include a single buffer medium layer or multiple buffer medium layers that are sequentially stacked.

For example, a thickness of the buffer layer 13 may be 1nm-5nm. For example, a thickness of the buffer layer 13 may be 1nm, 1.5nm, 2nm, 2.5nm, 3nm, 4nm, 4.5nm, or 5nm.

In step S104, referring to FIG. 1 and FIG. 2, the barrier layer 14 may be formed by using PVD, CVD, or ALD. The electron affinity of the barrier layer 14 is less than the electron affinity of the buffer layer 13.

For example, a material of the barrier layer 14 may include at least one of neodymium oxide, strontium oxide, germanium oxide, lanthanum oxide, hafnium oxide, gallium oxide, alumina, zirconium oxide, silicon oxide, ytterbium oxide, or magnesium oxide.

For example, the barrier layer 14 may include a single barrier material layer or multiple barrier material layers that are sequentially stacked.

For example, a thickness of the barrier layer 14 may be 1nm-5nm. For example, the thickness of the barrier layer 14 may be 1nm, 1.5nm, 2nm, 2.5nm, 3nm, 4nm, 4.5nm, or 5nm.

In step S105, referring to FIG. 1 and FIG. 2, the second electrode layer 15 may be formed on the barrier layer 14 by using PVD, CVD, PECVD, or ALD. A material of the second electrode layer 15 may include one or more of vanadium, niobium, ruthenium, tungsten, tantalum, titanium, titanium nitride, titanium tungsten, aluminum, titanium aluminum tungsten, aluminum nitride, aluminum titanium nitride, aluminum titanium nitride, hafnium, iridium, manganese, zinc, platinum, palladium, copper, or an alloy of the foregoing material. The second electrode layer 15 may be a single-layer structure or a multi-layer structure.

For example, a thickness of the second electrode layer 15 may be 10nm-2500nm.

According to the method for manufacturing the selector in the embodiments, the buffer layer 13 and the barrier layer 14 that are sequentially stacked are formed between the selection layer 12 and the second electrode layer 15, and the barrier 14 confines electrons to reduce a leakage current of the selector. Moreover, the electron affinities of the selection layer 12, the buffer layer 13, and the barrier layer 14 decrease sequentially, and the buffer layer 13 reduces performance fluctuations in the selector caused by a large electron affinity difference between the selection layer 12 and the barrier layer 14, thereby improving performance stability of the selector.

In some embodiments, referring to FIG. 1 and FIG. 2, a breakdown voltage of the buffer layer 13 is greater than a breakdown voltage of the barrier layer 14. In this way, the barrier layer 14 can be further prevented from being breakdown by a high partial voltage when the selector is turned on, thereby further reducing a risk of leakage of the selector, improving performance stability and reliability of the selector, and optimizing performance of a device and prolonging a service life of the device.

In some embodiments, referring to FIG. 1 and FIG. 2, a side surface of the selection layer 12 is in contact with the first electrode layer 11, and a barrier is formed between the selection layer 12 and the first electrode layer 11. A barrier is formed between a side surface of the barrier layer 14 away from the buffer layer 13 and the second electrode layer 15.

In the embodiment, the buffer layer 13 and the barrier layer 14 that are sequentially stacked are disposed between the selection layer 12 and the second electrode layer 15, such that electrons can be confined at the barrier between the selection layer 12 and the first electrode layer 11, as well as at the barrier between the barrier layer 14 and the second electrode layer 15, so as to avoid electron leakage, thereby reducing a leakage current of the selector.

In some embodiments, referring to FIG. 1 and FIG. 2, a difference between a work function of the first electrode layer 11 and the electron affinity of the selection layer 12 is greater than 2eV. A difference between a work function of the second electrode layer 15 and the electron affinity of the barrier layer 14 is greater than 2eV.

In some embodiments, the electron affinity of the selection layer 12 ranges from 2eV to 4.5eV. The electron affinity of the barrier layer 14 ranges from 1eV to 2eV. The electron affinity of the buffer layer 13 ranges from 1eV to 4.5eV.

In some embodiments, forming the buffer layer 13 on the side of the selection layer 12 away from the first electrode layer 11 includes: depositing a first conductive layer on the side of the selection layer 12 away from the first electrode layer 11, and after forming the barrier layer 14, annealing the selection layer 12, the first conductive layer, and the barrier layer 14, such that oxygen from the selection layer 12 and the barrier layer 14 oxidizes the first conductive layer to form the buffer layer 13.

In the embodiments, after the selection layer 12 is formed, the first conductive layer is formed on the selection layer 12, then steps of forming the barrier layer 14 and the second electrode layer 15 are performed, and then thermal annealing processing is performed on the structure, such that oxygen from the selection layer 12 and the barrier layer 14 oxidizes the first conductive layer, and a material of the first conductive layer is oxidized to form the buffer layer 13.

For example, a material of the first conductive layer may include at least one of titanium, nickel, zinc, chromium, molybdenum, tungsten, bismuth, antimony, indium, vanadium, niobium, manganese, neodymium, strontium, germanium, lanthanum, hafnium, gallium, aluminum, zirconium, silicon, ytterbium, or magnesium. The material of the buffer layer 13 includes metal oxide or non-metal oxide.

In some embodiments, an oxygen content on the side of the buffer layer 13 close to the barrier layer 14 is greater than an oxygen content on the side of the buffer layer 13 close to the selection layer 12.

In the embodiments, oxygen from the selection layer 12 and the barrier layer 14 oxidizes the first conductive layer to form the buffer layer 13, thereby achieving that the oxygen content on the side of the buffer layer 13 close to the barrier layer 14 is greater than the oxygen content on the side of the buffer layer 13 close to the selection layer 12, the electron affinity of the buffer layer 13 close to the barrier layer 14 is close to the electron affinity of the barrier layer 14, and the electron affinity of the buffer layer 13 close to the selection layer 12 is close to the electron affinity of the selection layer 12, thereby further avoiding performance fluctuation in the selector caused by the large electron affinity difference between the selection layer 12 and the barrier layer 14.

In the embodiments, the material of the first conductive layer and the thermal annealing parameters can be adjusted to enable the oxygen content of the buffer layer 13 to gradually increase in the direction from the selection layer 12 to the barrier layer 14.

In other embodiments, during the deposition of the buffer layer 13, multiple buffer medium layer may be deposited such that an oxygen content of the buffer medium layer on the side closer to the barrier layer 14 is greater than an oxygen content of the buffer medium layer closer to the selection layer 12.

In some embodiments, forming the selection layer 12 on the first electrode layer 11 includes: sequentially depositing multiple selection material layers on the first electrode layer 11, where an oxygen content of the selection material layer on the side away from the first electrode layer 11 is greater than an oxygen content of the selection material layer on the side close to the first electrode layer 11. In this way, the electron affinity of the contact interface between the selection layer 12 and the buffer layer 13 changes more smoothly, improving stability and performance of the selector.

In some embodiments, the oxygen content of the multiple selection material layer gradually increases in the direction from the selection layer 12 to the barrier layer 14, such that the difference between the electron affinity of the selection layer 12 and the electron affinity of the barrier layer 14 can be further weakened, improving stability and performance of the selector.

In an example, referring to FIG. 2, forming the selection layer 12 on the first electrode layer 11 includes: sequentially depositing a first selection material layer 121, a second selection material layer 122, a third selection material layer 123, and a fourth selection material layer 124 on the first electrode layer 11. A material of the first selection material layer 121 includes niobium monoxide (NbO), a material of the second selection material layer 122 includes niobium dioxide (NbO₂), a material of the third selection material layer 123 includes niobium trioxide (Nb₂O₃), and a material of the fourth selection material layer 124 includes oxygen-deficient niobium pentoxide (Nb₂O_{5-y}).

In some embodiments, forming the barrier layer 14 on the side of the buffer layer 13 away from the selection layer 12 includes: sequentially depositing multiple barrier material layers on the buffer layer 13, where an oxygen content of the barrier material layer away from the buffer layer 13 is greater than an oxygen content of the barrier material layer close to the buffer layer 13. The difference between the electron affinity of the selection layer 12 and the electron affinity of the barrier layer 14 is further weakened.

In some embodiments, referring to FIG. 1 and FIG. 2, the oxygen contents of the multiple barrier material layers gradually increase in the direction from the selection layer 12 to the barrier layer 14, further weakening the difference between the electron affinity of the selection layer 12 and the electron affinity of the barrier layer 14.

In some embodiments, the material of the selection layer 12 includes metal oxide. The material of the buffer layer 13 includes metal oxide or non-metal oxide. The material of the barrier layer 14 includes metal oxide or non-metal oxide. The buffer layer 13 is in contact with the selection layer 12. During the operation of the selector, oxygen in the selection layer 12 may be captured by the first electrode layer 11. The buffer layer 13 can supply oxygen to the selection layer 12, so as to maintain a balance of oxygen content in the selection layer 12, thereby improving performance stability of the selector.

The technical features in the above embodiments may be combined arbitrarily. For concise description, not all possible combinations of the technical features in the above embodiments are described. However, provided that they do not conflict with each other, all combinations of the technical features are to be considered to be within the scope of protection of the present disclosure.

The above-mentioned embodiments only describe several implementations of the present disclosure, and the description is specific and detailed, but should not be understood as a limitation on the protection scope of the present disclosure. It should be noted that, for a person of ordinary skill in the art, various variations and improvements can be further made without departing from the conception of the present disclosure, and these all fall within the protection scope of the present disclosure. Therefore, the protection scope of the present disclosure should be subject to the appended claims.

What is claimed is:

1. A selector, wherein the selector comprises a first electrode layer, a selection layer, a buffer layer, a barrier layer, and a second electrode layer;
the selection layer, the buffer layer, and the barrier layer are stacked between the first electrode layer and the second electrode layer; and
an electron affinity of the barrier layer is less than an electron affinity of the selection layer, and an electron affinity of the buffer layer is between the electron affinity of the selection layer and the electron affinity of the barrier layer.

2. The selector according to claim 1, wherein a side surface of the selection layer is in contact with the first electrode layer, and a barrier is formed between the selection layer and the first electrode layer; and
a barrier is formed between a side surface of the barrier layer away from the buffer layer and the second electrode layer.

3. The selector according to claim 2, wherein a difference between a work function of the first electrode layer and the electron affinity of the selection layer is greater than 2eV; and
a difference between a work function of the second electrode layer and the electron affinity of the barrier layer is greater than 2eV.

4. The selector according to claim 1, wherein the electron affinity of the selection layer ranges from 2eV to 4.5eV, and the electron affinity of the barrier layer ranges from 1eV to 2eV.

5. The selector according to claim 1, wherein an oxygen content on a side of the buffer layer close to the barrier layer is greater than an oxygen content on a side of the buffer layer close to the selection layer.

6. The selector according to claim 5, wherein the oxygen content of the buffer layer gradually increases in a direction from the selection layer to the barrier layer.

7. The selector according to claim 1, wherein the selection layer comprises multiple selection material layers, and an oxygen content of the selection material layer on a side away from the first electrode layer is greater than an oxygen content of the selection material layer on a side close to the first electrode layer.

8. The selector according to claim 7, wherein the oxygen contents of the multiple selection material layers gradually increase in a direction from the selection layer to the barrier layer.

9. The selector according to claim 1, wherein the barrier layer comprises multiple barrier material layers, and an oxygen content of the barrier material layer on the side away from the buffer layer is greater than an oxygen content of the barrier material layer on the side close to the buffer layer.

10. The selector according to claim 1, wherein a breakdown voltage of the buffer layer is greater than a breakdown voltage of the barrier layer.

11. The selector according to claim 1, wherein an oxygen affinity of the buffer layer is less than an oxygen affinity of the barrier layer.

12. The selector according to claim 1, wherein a material of the barrier layer comprises at least one of neodymium oxide, strontium oxide, germanium oxide, lanthanum oxide, hafnium oxide, gallium oxide, alumina, zirconium oxide, silicon oxide, ytterbium oxide, or magnesium oxide;
a material of the buffer layer comprises at least one of titanium oxide, nickel oxide, zinc oxide, chromium oxide, molybdenum oxide, tungsten oxide, bismuth oxide, antimony oxide, indium oxide, vanadium oxide, niobium oxide, manganese oxide, neodymium oxide, strontium oxide, germanium oxide, lanthanum oxide, hafnium oxide, gallium oxide, alumina, zirconium oxide, silicon oxide, yttrium oxide, or magnesium oxide; and
a material of the selection layer comprises at least one of niobium oxide, vanadium oxide, germanium telluride, germanium selenide, iron oxide, neodymium nickel oxide, samarium nickel oxide, lanthanum cobalt oxide, or gadolinium cobalt oxide.

13. A method for manufacturing a selector, comprising:
providing a substrate, and forming a first electrode layer on the substrate;
forming a selection layer on the first electrode layer;
forming a buffer layer on a side of the selection layer away from the first electrode layer;
forming a barrier layer on a side of the buffer layer away from the selection layer, wherein an electron affinity of the barrier layer is less than an electron affinity of the selection layer, and an electron affinity of the buffer layer is between the electron affinity of the selection layer and the electron affinity of the barrier layer; and
forming a second electrode layer on a side of the barrier layer away from the buffer layer.

14. The method according to claim 13, wherein forming the buffer layer on the side of the selection layer away from the first electrode layer comprises:
depositing a first conductive layer on the side of the selection layer away from the first electrode layer; and
after forming the barrier layer, annealing the selection layer, the first conductive layer, and the barrier layer, such that oxygen from the selection layer and the barrier layer oxidizes the first conductive layer to form the buffer layer.

15. The method according to claim 14, wherein an oxygen content on a side of the buffer layer close to the barrier layer is greater than an oxygen content on a side of the buffer layer close to the selection layer.

16. The method according to claim 13, wherein forming the selection layer on the first electrode layer comprises:
sequentially depositing multiple selection material layers on the first electrode layer, an oxygen content of the selection material layer on a side away from the first electrode layer being greater than an oxygen content of the selection material layer on a side close to the first electrode layer.

17. The method according to claim 13, wherein forming the barrier layer on the side of the buffer layer away from the selection layer comprises:
sequentially depositing multiple barrier material layers on the buffer layer;
wherein an oxygen content of the barrier material layer away from the buffer layer being greater than an oxygen content of the barrier material layer close to the buffer layer.

18. The method according to claim 13, wherein a difference between a work function of the first electrode layer and the electron affinity of the selection layer is greater than 2eV; and
a difference between a work function of the second electrode layer and the electron affinity of the barrier layer is greater than 2eV.

19. The method according to claim 13, wherein the electron affinity of the selection layer ranges from 2eV to 4.5eV, and the electron affinity of the barrier layer ranges from 1eV to 2eV.

20. The method according to claim 13, wherein a material of the barrier layer comprises at least one of neodymium oxide, strontium oxide, germanium oxide, lanthanum oxide, hafnium oxide, gallium oxide, alumina, zirconium oxide, silicon oxide, ytterbium oxide, or magnesium oxide;
a material of the buffer layer comprises at least one of titanium oxide, nickel oxide, zinc oxide, chromium oxide, molybdenum oxide, tungsten oxide, bismuth oxide, antimony oxide, indium oxide, vanadium oxide, niobium oxide, manganese oxide, neodymium oxide, strontium oxide, germanium oxide, lanthanum oxide, hafnium oxide, gallium oxide, alumina, zirconium oxide, silicon oxide, yttrium oxide, or magnesium oxide; and
a material of the selection layer comprises at least one of niobium oxide, vanadium oxide, germanium telluride, germanium selenide, iron oxide, neodymium nickel oxide, samarium nickel oxide, lanthanum cobalt oxide, or gadolinium cobalt oxide.
